(19) United States
(12) Patent Application Publication
(10) Pub. No.: US 2005/0003632 A1
(43) Pub. Date: Jan. 6, 2005

(54) Method for cutting a sapphire substrate for a semiconductor device

(76) Inventors: Masaru Onishi, Aichi-ken (JP); Masaki Hashimura, Aichi-ken (JP)

Correspondence Address: MCGINN & GIBB, PLLC, 8321 OLD COURTHOUSE ROAD, SUITE 200, VIENNA, VA, 22182-3817, US

(21) Appl. No.: 10/488,867

(22) PCT Filed: Jul. 12, 2002
(86) PCT No.: PCT/JP02/07139

(30) Foreign Application Priority Data
Sep. 11, 2001 (JP) 2001274525

(51) Int. Cl. H01L 21/301; H01L 21/46; H01L 21/78

(52) U.S. Cl. 438/462

(57) ABSTRACT

A method for cutting a sapphire substrate whose A plane functions as a main surface is carried out after forming a semiconductor device or in order to form a device. Here a just A plane of the sapphire substrate is represented by a (11-20) plane, a line of intersection of the main surface and at least one of a (10-12) plane and a (0-112) plane is defined as a base line and a direction which an angle decreases as it reaches the axis c is defined as a positive direction. In that case, a separation line is formed along a first direction which makes an angle of 0 to 4 degrees with the line of intersection and a second direction which is perpendicular to the first direction.

### TECHNICAL FIELD

The present invention relates to a method for cutting a sapphire substrate whose A plane functions as a main surface. The present invention is especially useful as a method for cutting into each individual device after forming a semiconductor device comprising group III nitride compound semiconductor on a sapphire substrate whose A plane functions as a main surface. In the present specification, an A plane of a sapphire substrate also include an A plane which is offset by 2 degrees or less from just a-axis. In addition, in the present specification, a precise A plane {11-20} is expressed as “a just A plane” in order to distinguish it from other offset A planes. And the Miller indices are represented by adding a minus sign in front of the Miller Indices instead of bars over the Miller indices.

### BACKGROUND ART

It is known that development of a group III nitride compound semiconductor device represented by a blue-light or green-light emitting diode and a blue-light and green-light emitting laser diode has been growing. And the inventors of the present invention develop a method in which a group III nitride compound semiconductor light-emitting device is formed on a sapphire substrate whose A plane functions as a main surface.

It is difficult to cut and separate the device into each piece of light-emitting device after forming a group III nitride compound semiconductor light-emitting device on a sapphire substrate whose A plane functions as a main surface. Actually, when a just A plane is represented by (11-20) plane, a scribe line is formed parallel to at least one orientation of the c axis [0001] and the m axis [1-100] on the (11-20) plane in order to separate the group III nitride compound semiconductor light-emitting device along the scribe line. However, considerable numbers of cracks and defects are generated and yield rate of light-emitting devices significantly decreases.

In order to overcome this problem, as shown in a conventional invention of Japanese Patent Application Laid-open No. H8-88201 which was invented by the present inventors, scribe lines which incline at an angle of about ±45 degrees with respect to the c axis <0001> and cross in a direction perpendicular to each other are formed on the just A plane of a sapphire substrate, i.e., (11-20) plane. Also, as shown in Japanese Patent Application Laid-open No. H9-219560, it is suggested to cleave a sapphire substrate at an angle of 58±5° or 40±5° to the direction vertical from the axis c of the sapphire substrate in order to obtain a mirror surface of a laser cavity of a laser diode.

Even by employing those conventional techniques, cracks and defects are generated when the sapphire substrate, whose A plane functions as a main surface for forming a group III nitride compound semiconductor light-emitting device, is separated into each square pieces and the yield rate of the light-emitting devices becomes only 93%. That was not a satisfactory result. Then, the inventors of the present invention conducted a series of experiments to control an angle extremely accurately and to optimize scribe lines each of which is perpendicular with each other and formed on the sapphire substrate whose A plane functions as a main surface. As a result, the inventors of the present invention succeeded improving the yield rate to be 98% without cracks and defects.

### DISCLOSURE OF THE INVENTION

The present invention has been accomplished in order to overcome the aforementioned drawbacks. That is, the first aspect of the present invention provides a method for cutting a sapphire substrate whose A plane functions as a main surface after forming a semiconductor device or in order to form a device, where a just A plane of a sapphire substrate is represented by a (11-20) plane and a line of intersection of the main surface and at least one of a (10-12) plane and a (0-112) plane is defined as a base line and a direction which an angle decreases as it reaches the axis c is defined as a positive direction of angle, a separation line is formed along a first direction which makes an angle of 0 to 4 degrees with the line of intersection and a second direction which is perpendicular to the first direction.

The second aspect of the present invention is a method wherein the sapphire substrate is separated by carrying out scribing on the main surface of the substrate in the first direction and the second direction.

The main surface may be alternatively the back surface of the sapphire substrate on which a semiconductor device is formed. Here the second direction which is perpendicular to the first direction may include errors of about 2 degrees or so.

The third aspect of the present invention is a method wherein the first direction makes an angle of 0.18 to 2.5 degrees with the line of intersection.

FIG. 1 illustrates relationship of a separation line of the present invention between each direction of lines on a just A plane represented by a (11-20) plane. Signs c and m represent the axis c [0001] and the axis m [1-100], respectively. A Line referred to as line 45 represents a conventional scribe line which makes an angle of 45 degrees with the axis c and the axis m, respectively. Two lines represented by r2 are lines of intersection of the A plane (11-20) and two planes perpendicular to the A plane, or R plane (1-102) and R plane (−1102), respectively. One line r13 is line of intersection of the A plane (11-20) and one plane which is not perpendicular to the A plane, or at least one of R plane (10-12) and (0-112). The other line r13 is line of intersection of the A plane (11-20) and one plane which is not perpendicular to the A plane, or at least one of R plane (−1012) and (01-12). And a region represented by P shows the first direction of the present invention and a region represented by Q shows the second direction of the present invention.

Each of the line r2 and the line r13 makes an angle of about 32 degrees and about 51.7 degrees, respectively, with the axis c. And the direction represented by P makes an angle of about 47.7 to 51.7 degrees with axis c. The direction represented by Q makes an angle of about 38.3 to 42.3 degrees with axis c. By separating the sapphire substrate in the directions of P and Q, the sapphire substrate can be divided into devices each of which has a perpendicular separation surface and a square shape. Although the accurate reason why the sapphire substrate can be securely separated into each devices by separating the substrate along the directions P and Q is not clear, the regions of the angles described above has critical effect as explained below.

### BRIEF DESCRIPTION OF THE DRAWINGS

FIG. 1 is a view explaining the direction of separating a sapphire substrate whose A plane functions as a main surface according to the present invention.

FIG. 2 is a graph showing yield rate of light-emitting devices in an embodiment of the present invention, together with those of a conventional embodiment and a modified embodiment.

FIGS. 3A-3C are exterior views of a wafer from which a sapphire substrate is separated after forming a GaN layer. FIG. 3A shows an acceptable product and FIGS. 3B and 3C show rejected products.

### BEST MODE FOR CARRYING OUT THE INVENTION

Embodiments of the present invention will next be described based on concrete examples. The scope of the present invention, however, is not limited to the embodiment described below.

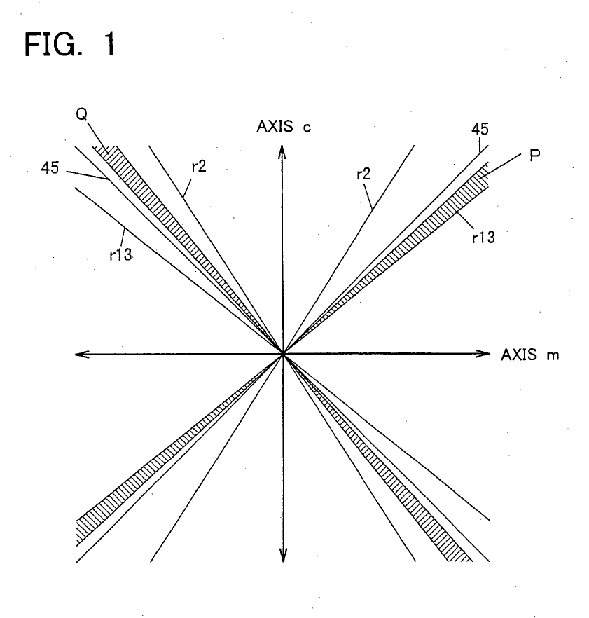

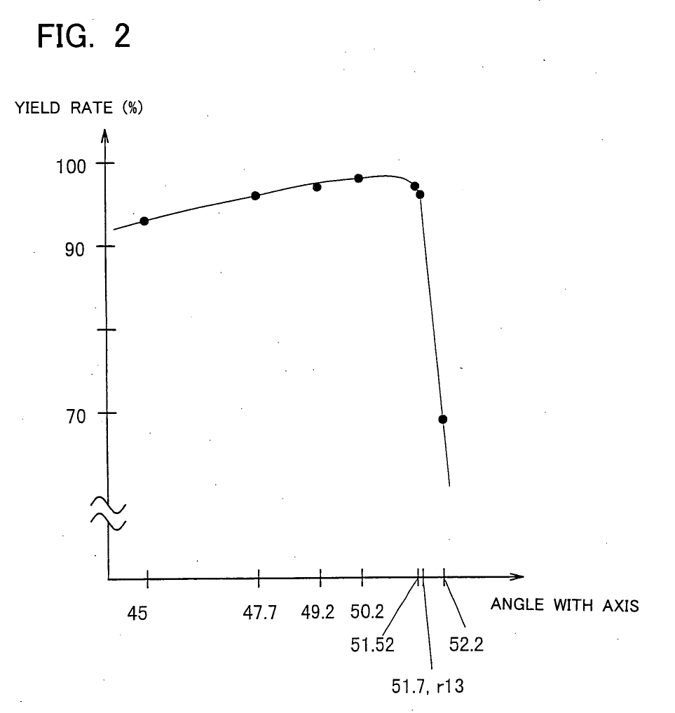

Seven sapphire substrates (wafers), each of whose thickness is 150 μm and A plane functions as a main surface for crystal growth, are prepared. An AlN buffer layer and a GaN layer having thickness of 6 μm are deposited in sequence on each of the sapphire substrate. Then, seven scribe lines each having depth of 5 μm are formed on the back surface of the seven sapphire substrates in first directions which make angles of 45.00 degrees, 47.70 degrees, 49.20 degrees, 50.20 degrees, 51.52 degrees, 51.70 degrees, and 52.20 degrees, respectively, with the axis c and in second directions which are perpendicular to each of the first directions, respectively. And a direction r13 shown in FIG. 1 makes an angle of 51.70 degrees with the axis c. The sapphire substrates are broken through scribing process along the scribe lines by using rollers, to thereby separate the substrate into chips of 50 μm dice. The yield rate of the devices is described below. FIG. 2 also shows its result.

| | | Proportion |
|---|---|---|
| | | of |
| The angle which the first | Yield rate of | defective |
| direction and the axis c make | the devices | products |
| 45.00 degrees | 93% | 7% |
| (the conventional invention) | | |
| 47.70 degrees | 96% | 4% |
| (the present invention) | | |
| 49.20 degrees | 97% | 3% |
| (the present invention) | | |
| 50.20 degrees | 98% | 2% |
| (the present invention) | | |
| 51.52 degrees | 97% | 3% |
| (the present invention) | | |
| 51.70 degrees | 96% | 4% |
| (the present invention, r13) | | |
| 52.20 degrees | 69% | 31% |
| (the comparative invention) | | |

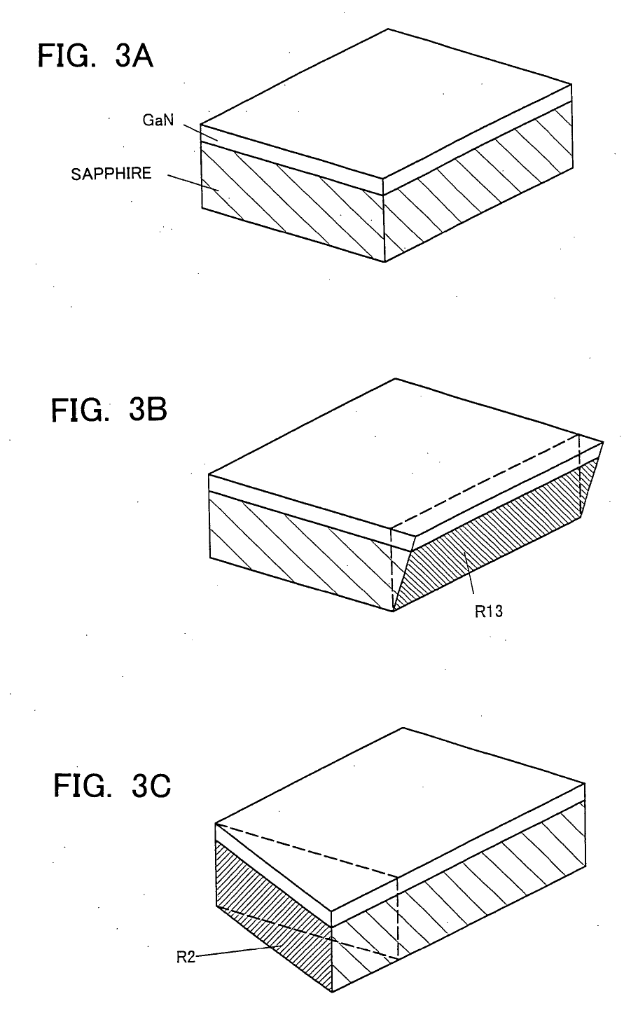

By dividing the sapphire substrate in the first direction and the second direction which is perpendicular to the first direction, yield (proportion of defective products) of a device can be remarkably improved as shown in FIG. 2. Here the first direction is the direction that the angle between the first direction and the axis c is smaller by 0 to 4 degrees from a line of intersection r13. The line of intersection r13 is made by the A plane (11-20) and R plane which is not perpendicular to the A plane. FIGS. 3A-3C illustrate views of an acceptable product and a rejected product. As shown in FIG. 3A, an acceptable product is a chip of rectangular parallelepiped whose cutting surface is almost perpendicular to the main surface of the substrate. On the contrary, a rejected product has an undesirable cutting surface such as R plane R13 which is not perpendicular to A plane as shown in FIG. 3B or R plane R2 which is perpendicular to A plane as shown in FIG. 3C. As a result, the chip comprising such undesirable plane is rejected along with chips adjacent to the rejected chip.

In the above embodiment, after forming the AlN buffer layer and the GaN layer on the sapphire substrate (wafer), scribing treatment is carried out from the back surface of the sapphire substrate. Alternatively, in conducting the embodiment of the present invention, semiconductor layers which are formed on the sapphire substrate whose A plane functions as its main surface for crystal growth may have any compositions, and they may not be limited to, e.g., a group III nitride compound semiconductor. Further alternatively, dividing process of the sapphire substrate can be carried out after forming each device. As a method for dividing and cutting the sapphire substrate, any arbitrary method for cutting the sapphire substrate can be employed in place of carrying out breaking after scribing treatment. A feature of the present invention is the direction of a boundary on a substrate at which the sapphire substrate whose A plane functions as its main surface is cut and divided, so any conditions other than that may be included in scope of the present invention.

While the present invention has been described with reference to the above embodiments as the most practical and optimum ones, the present invention is not limited thereto, but may be modified as appropriate without departing from the spirit of the invention.

1. A method for cutting a sapphire substrate whose A plane functions as a main surface after forming a semiconductor device or in order to form a device, wherein
where a just A plane of said sapphire substrate is represented by a (11-20) plane and a line of intersection of said main surface and at least one of a (10-12) plane and a (0-112) plane is defined as a base line and a direction which an angle decreases as it reaches the axis c is defined as a positive direction of angle,
a separation line is formed along a first direction which makes an angle of 0 to 4 degrees with said line of intersection and a second direction which is perpendicular to said first direction.

2. A method for cutting a sapphire substrate whose A plane functions as a main surface after forming a semiconductor device or in order to form a device, wherein
where a just A plane of said sapphire substrate is represented by a (11-20) plane and a line of intersection of said main surface and at least one of a (10-12) plate and a (0-112) plane is defined as a base line and a direction which an angle decreases as it reaches the axis c is defined as a positive direction of angle,
scribing on said main surface along a first direction which makes an angle of 0 to 4 degrees with said line of intersection and a second direction which is perpendicular to said first direction, and
separating said substrate into each dice.

3. A method for cutting a sapphire substrate according to claim 1, wherein said first direction makes an angle of 0.18 to 2.5 degrees with said line of intersection.
